(19) United States
(12) Patent Application Publication
(10) Pub. No.: US 2025/0158571 A1
(43) Pub. Date: May 15, 2025

(54) BROADBAND COUPLER-BASED BALUN CONTINUOUS ACTIVE LOAD MODULATION POWER AMPLIFIER

(71) Applicant: Georgia Tech Research Corporation, Atlanta, GA (US)

(72) Inventors: Tzu-Yuan Huang, Atlanta, GA (US); Hua Wang, Atlanta, GA (US)

(21) Appl. No.: 18/834,650

(22) PCT Filed: Feb. 9, 2023
(86) PCT No.: PCT/US2023/062283

§ 371 Date: Jul. 31, 2024

Related U.S. Application Data
(60) Provisional application No. 63/267,719, filed on Feb. 9, 2022.

(51) Int. Cl. H03F 1/02; H03F 3/21

(52) U.S. Cl. CPC H03F 1/0205; H03F 3/21; H03F 2200/09

(57) ABSTRACT

The present disclosure provides a system for a wideband coupler balun with a load modulated power amplifier wherein the system can comprise a first port, a second port, a differential port, a differential main power amplifier, and an auxiliary power amplifier. The first port can be electrically connected to a first coupled line coupler. The second port can be electrically connected to a second coupled line coupler. The differential port can be electrically connected to the first and second coupled line coupler. The differential main amplifier can be configured to be electrically connected to the differential port. The auxiliary power amplifier can be configured to be electrically connected to the first port.

### CROSS-REFERENCE TO RELATED APPLICATIONS

This application claims the benefit of U.S. Provisional Application Ser. No. 63/267,719, filed on 9 Feb. 2022, which is incorporated herein by reference in its entirety as if fully set forth below.

### FIELD OF INVENTION

The various embodiments of the present disclosure relate to balun circuits.

### BACKGROUND

Millimeter-Wave (mm-Wave) spectrum offers wide frequency brands to support a large range of next generation wireless communication and sensing applications. In particular, mm-Wave wireless communication links primarily aim at providing massive data throughputs among wireless nodes. For example, multistandard 5G mm-Wave systems need to cover noncontiguous FR2 frequency bands, necessitating wideband mm-Wave 5G front-end modules (FEM) and systems to support cross-country/region roaming, especially for user equipment (UE) devices.

Next generation millimeter-wave (mm-Wave) power amplifiers (PAs) need to support multistandard communication systems with wide bandwidth, complex modulation, and high energy efficiency. For instance, desired PAs should maintain excellent linearity, meaning the ability to produce signals that are accurate copies of the input at increased power levels, through the dynamic range demanded by complex modulations. Furthermore, desired PAs should provide high efficiency at power back off (PBO) regions. As one skilled in the art will appreciate, PBO regions for PAs is the power level for a PA slightly below the saturation point, allowing said PA to maintain linearity during operation despite receiving a slight increase in power. Current mm-Wave PA architectures with power backoff (PBO) efficiency enhancement, such as Doherty, outphasing PAs, and the like, typically only support limited carrier bandwidth. Outphasing PAs require the generation of high speed outphasing signals, which limits the modulation speed and increases baseband computation overhead. Doherty PAs are typically bandwidth constrained due to their impedance inverters.

Accordingly, to address the aforementioned challenges, there exists a need for a wideband PA architecture supporting high PBO efficiency and the ability to be fully integrated into mm-Wave designs.

### SUMMARY

An exemplary embodiment of the present disclosure provides a system for a wideband coupler balun with a load modulated power amplifier wherein the system can comprise a first port, a second port, a differential port, a differential main power amplifier, and an auxiliary power amplifier. The first port can be electrically connected to a first coupled line coupler. The second port can be electrically connected to a second coupled line coupler. The differential port can be electrically connected to the first and second coupled line coupler. The differential main amplifier can be configured to be electrically connected to the differential port. The auxiliary power amplifier can be configured to be electrically connected to the first port.

In any of the embodiments disclosed herein, the second port can be electrically terminated with a single ended output load.

In any of the embodiments disclosed herein, the first coupled line coupler and the second coupled line coupler can be electrically connected in series.

In any of the embodiments disclosed herein, the system can further be configured to operate at a center frequency wherein the first and second coupled line couplers are configured to have a quarter wave electrical length of the center frequency.

In any of the embodiments disclosed herein, the first coupled line coupler and the second coupled line coupler can be configured to have a coupling factor of 1/√2 between the first coupled line coupler and the second coupled line coupler.

In any of the embodiments disclosed herein, the auxiliary power amplifier, when powered on, can be configured to inject a signal on the first port. The auxiliary power amplifier, when powered off, may cause the differential main power amplifier to drive the coupler balun.

In any of the embodiments disclosed herein, the auxiliary power amplifier, when powered on, can be further configured to modulate a load impedance for the differential main power amplifier.

In any of the embodiments disclosed herein, the balun can be configured such that the load impedance for the differential main power amplifier can be modulated based on a current ratio between the differential main power amplifier and the auxiliary power amplifier.

In any of the embodiments disclosed herein, the differential main power amplifier, when powered on, can be configured to inject a signal on the differential port.

Another embodiment of the present disclosure provides a wideband coupler balun with a load modulated power amplifier, wherein the balun can comprise one or more coupled line couplers, a plurality or ports, a differential main power amplifier, and an auxiliary power amplifier. The wideband coupler balun can be configured to receive an unbalanced signal at the first port and return a balanced signal at the second port. The one or more coupled line couplers can be configured to operate at a center frequency. The plurality of ports can comprise a first port, a second port, and a differential port. The differential main power amplifier can be electrically connected to a differential port in the plurality of ports. The auxiliary power amplifier can be electrically connected to a first port in the plurality of ports.

In any of the embodiments disclosed herein, the second port in the plurality of ports may be electrically terminated with a single ended output load.

In any of the embodiments disclosed herein, the one or more coupled line couplers can be electrically connected in series.

In any of the embodiments disclosed herein, the one or more coupled line couplers, when operating at the center frequency can be configured to have a quarter wave electrical length of the center frequency.

In any of the embodiments disclosed herein, the one or more coupled line couplers can be further configured to have a coupling factor of 1/√2 between the one or more coupled line couplers.

In any of the embodiments disclosed herein, the auxiliary power amplifier, when powered on, can be configured to inject a signal on the first port. The auxiliary power amplifier, when powered off, may cause the differential amplifier to drive the coupler balun.

In any of the embodiments disclosed herein, the auxiliary power amplifier, when powered on can be further configured to modulate a load impedance for the differential main power amplifier.

In any of the embodiments disclosed herein, the load impedance for the differential main power amplifier can be modulated based on a current ratio between the differential main power amplifier and the auxiliary power amplifier.

In any of the embodiments disclosed herein, the differential main power amplifier, when powered on, can be configured to inject a signal on the differential port.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF DRAWINGS

The above and further aspects of this invention are further discussed with reference to the following description in conjunction with the accompanying drawings, in which like numerals indicate like structural elements and features in various figures. The drawings are not necessarily to scale, emphasis instead being placed upon illustrating principles of the invention. The figures depict one or more implementations of the inventive devices, by way of example only, not by way of limitation.

FIG. 1 is an exemplary schematic of the structure and elements of a wideband coupler balun with load modulated power amplifiers, in accordance with an exemplary embodiment of the present disclosure.

FIG. 2 is another exemplary schematic of the structure and elements of a wideband coupler balun with load modulated power amplifiers, in accordance with an exemplary embodiment of the present disclosure.

FIG. 3 is an exemplary schematic of a cascading wideband coupler balun, in accordance with an exemplary embodiment of the present disclosure.

FIG. 4 is an exemplary system schematic of a wideband coupler balun with load modulated power amplifiers, in accordance with an exemplary embodiment of the present disclosure.

### DETAILED DESCRIPTION

The following detailed description should be read with reference to the drawings, in which like elements in different drawings are identically numbered. This description enables one skilled in the art to make and use the invention, and describes several embodiments, adaptations, variations, alternatives and uses of the invention, including what is presently believed to be the best mode of carrying out the invention. Any one or more of the teachings, expressions, versions, examples, etc. described herein may be combined with any one or more of the other teachings, expressions, versions, examples, etc. that are described herein. The following-described teachings, expressions, versions, examples, etc. should therefore not be viewed in isolation relative to each other. Various suitable ways in which the teachings herein may be combined will be readily apparent to those skilled in the pertinent art in view of the teachings herein. Such modifications and variations are intended to be included within the scope of the claims.

It must also be noted that, as used in the specification and the appended claims, the singular forms “a,” “an” and “the” include plural references unless the context clearly dictates otherwise. For example, reference to a component is intended also to include composition of a plurality of components. References to a composition containing “a” constituent is intended to include other constituents in addition to the one named.

Also, in describing the exemplary embodiments, terminology will be resorted to for the sake of clarity. It is intended that each term contemplates its broadest meaning as understood by those skilled in the art and includes all technical equivalents which operate in a similar manner to accomplish a similar purpose.

By “comprising” or “containing” or “including” is meant that at least the named compound, element, particle, or method step is present in the composition or article or method, but does not exclude the presence of other compounds, materials, particles, method steps, even if other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a composition does not preclude the presence of additional components than those expressly identified.

The materials described as making up the various elements of the invention are intended to be illustrative and not restrictive. Many suitable materials that would perform the same or a similar function as the materials described herein are intended to be embraced within the scope of the invention. Such other materials not described herein can include, but are not limited to, for example, materials that are developed after the time of the development of the invention.

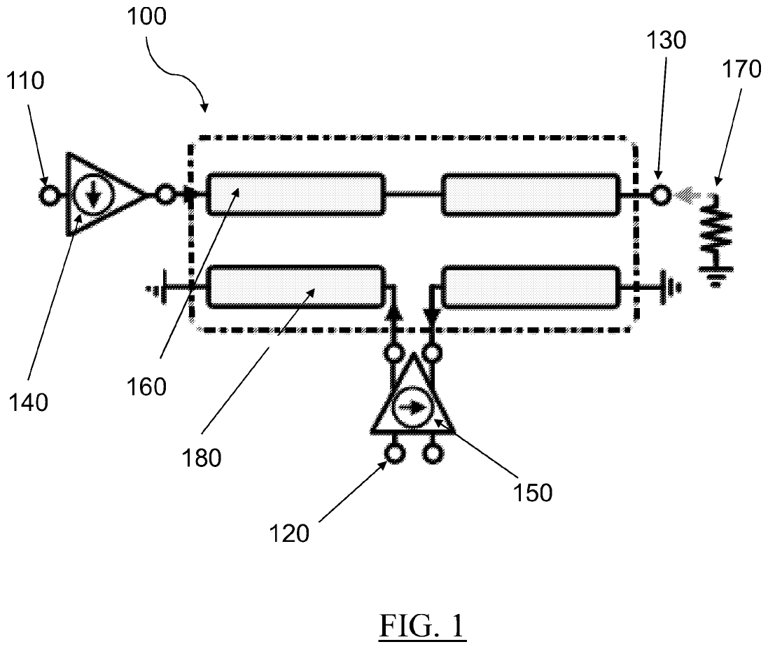

FIG. 1 is an exemplary schematic of the structure and elements of a wideband coupler balun 100 with load modulated power amplifiers, in accordance with an exemplary embodiment of the present disclosure. As one skilled in the art may appreciate, the use of a first set of coupled line couplers 160 that can be electrically connected in series and a second set of coupled line coupler 180 that may also be electrically connected in series can behave as a balun, e.g., the structure shown in FIG. 1. In an exemplary embodiment, the electrical length of the first set of coupled line couplers 160 and the second set of coupled line couplers may be 90°, wherein the coupling factor between the sets of coupled line couplers may be 1/√2, though the disclosure is not limited to these specific values. The wideband coupler balun 100 can also include a first port 110, a differential port 120, and a second port 130. The first port 110 can be electrically connected to an auxiliary power amplifier 140 which therein can be electrically connected to the first set of coupled line couplers as shown in FIG. 1 The differential port 120 can be electrically connected to a differential power amplifier 150 which therein can be connected to the second set of coupled line couplers 180. The second port 130, also as shown in FIG. 1, can be electrically terminated with a single ended output load.

In some embodiments, the auxiliary power amplifier 140 may be turned off within the wideband coupler balun 100, such as during active load modulation. As one skilled in the art will appreciate, load modulation can enable the transfer of data or information from a transponder and back to said transponder. If the auxiliary power amplifier 140 is turned off during active load modulation, the differential power amplifier 150 may operate as the main power amplifier thus meaning overall performance of the power amplifier for the wideband coupler balun 100 may depend on only the differential power amplifier 150. Conversely, if the auxiliary power amplifier 140 for the wideband coupler balun 100 is turned on, the auxiliary power amplifier can inject a signal on the first port 110. Resultantly, the overall load impedance for the power amplifier of the wideband coupler balun 100 can be represented as the following current ratio: I_{Aux}/Iₘₐᵢₙ, wherein I_{Aux} is the current within the auxiliary power amplifier 140 and Iₘₐᵢₙ is the current within the differential power amplifier 150. As will be appreciated, load impedance is a vital characteristic in systems as properly matched load impedance can ensure maintaining signal level at both the input and output of a system. With respect to the present disclosure, the wideband coupler balun 100 modulating the overall load impedance of the power amplifier based on the current ratio can discourage overdriving, which can protect the power amplifier while encouraging linearity of performance and back off efficiency enhancement.

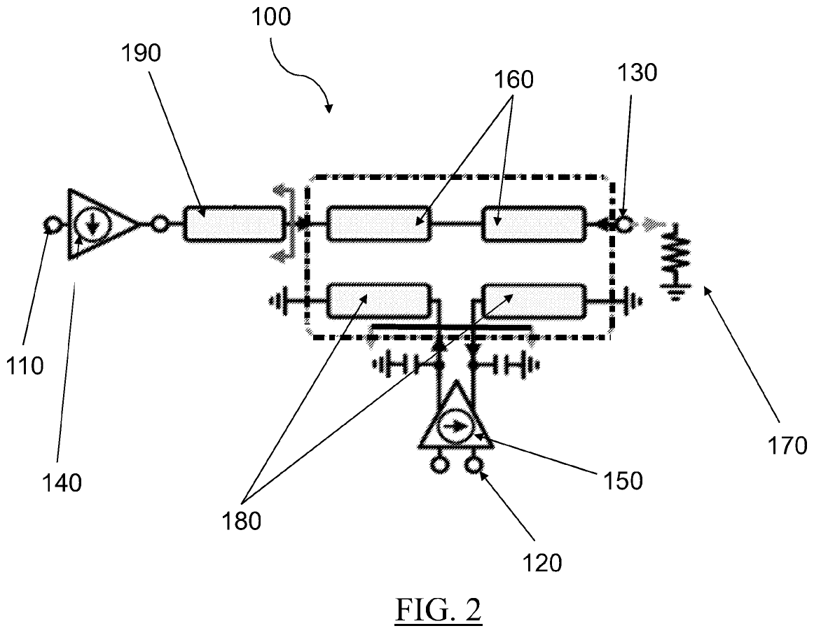

FIG. 2 is another exemplary schematic of the structure and elements of a wideband coupler balun with load modulated power amplifiers, in accordance with an exemplary embodiment of the present disclosure. In some embodiments, such as printed circuit boards (PCBs), the wideband coupler balun 100 structure can have a larger component footprint, which may present a challenge for implementation at mm-Wave frequency applications. An alternate structure of the wideband coupler balun 100, as illustrated in FIG. 2, may include certain features such as an embedded transmission line 190 and reduced electrical length for the sets of coupled line couplers. For example, the first set of coupled line couplers 160 and the second set of coupled line couplers 180 may have an electrical length of less than 90°. In some embodiments, as shown in FIG. 2, the embedded transmission line 190 can be electrically connected to the auxiliary power amplifier 140 and therein connected to the first port 110. An advantage of using the embedded transmission line 190 and reduced electrical length for the sets of coupled line couplers is that the wideband coupler balun 100 can be reduced in size and may allow for improved impedance matching of the differential power amplifier 150. Additionally, the structure and features as shown in FIG. 2 discourages overall power amplifier performance degradation, which can occur due to the phase delay between the auxiliary power amplifier 140 and the differential power amplifier 150. As one skilled in the art will appreciate, phase delay with amplifiers refers to the time difference between the input and output signals within an amplifier. With respect to the present disclosure, a phase delay that is greater than 90° between the differential power amplifier 150 and the auxiliary power amplifier 140 could result in overall performance degradation of the power amplifier. The overall performance degradation of the power amplifier of the wideband coupler balun 100 can be due to impedance loading at the auxiliary power amplifier 140.

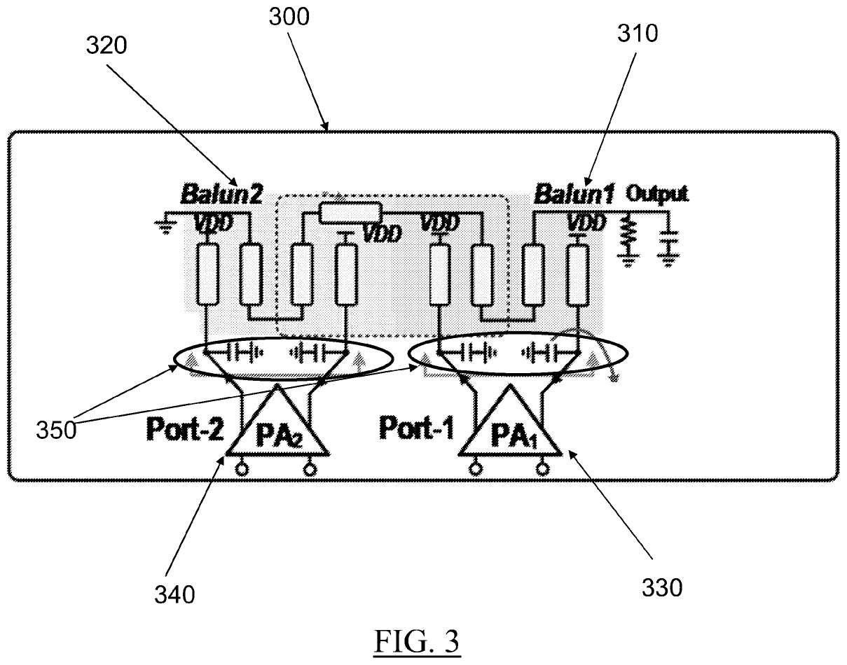

FIG. 3 is an exemplary schematic of a cascading wideband coupler balun structure 300, in accordance with an exemplary embodiment of the present disclosure. In some embodiments, it may be desirable to guarantee both the differential power amplifier 150 and auxiliary power amplifier 140 can operate under differential operation. One advantage of both the differential power amplifier 150 and the auxiliary power amplifier 140 operating under differential operation can include enabling broadband capacitive neutralization for device gain and stability. This advantage can be realized by cascading a second wideband coupler balun 320 with a first wideband coupler balun 310, as shown in FIG. 3. Features of the cascading wideband coupler balun structure 300 may include using a smaller electrical length for each set of coupled line couplers to reduce footprint of the overall structure. For example, the electrical length of each set of coupled line couplers may be 30° to allow for reduction of the cascading wideband coupler structure 300 footprint. Similar to the feature shown in FIG. 2, an embedded transmission line 190 may also be used in this cascading wideband balun structure 300 to maintain phase difference between the power amplifiers of the first wideband coupler balun structure 310 and the power amplifiers second wideband balun structure 320.

In some embodiments, the power amplifier of the first wideband coupler balun 310 may be denoted as PA₁ 330 and recognized as the auxiliary power amplifier 140 while the second power amplifier of the second wideband coupler balun structure 320 may be denoted as PA₂ 340 and recognized as the differential power amplifier 150. With PA₁ 330 and PA₂ 340 recognized as the auxiliary power amplifier 140 and the differential power amplifier 150, respectively, the cascading wideband balun coupler structure 300 may operate in a first operational mode known as Mode-1. In some embodiments, the cascading wideband balun coupler structure 300 while in Mode-1 may operate with a center frequency from the frequency range of 30-57 GHz. Conversely, with PA₁ 330 and PA₂ 340 recognized as the differential power amplifier 150 and auxiliary power amplifier 140 the differential power amplifier 150, respectively, the cascading wideband coupler structure 300 may operate in a second operational mode known as Mode-2. In some embodiments, the cascading wideband balun coupler structure 300 while in Mode-2 may operate with a center frequency from the frequency range of 20-30 GHz and 57-65 GHz. Advantages of the cascading wideband coupler balun structure 300 using Mode-1 and Mode-2 operational modes may include maintaining phase delay between the power amplifiers of each wideband coupler balun structure during active load modulation, maintaining high power back off efficiency in specific frequency ranges, and improving linearity of overall power amplifier performance.

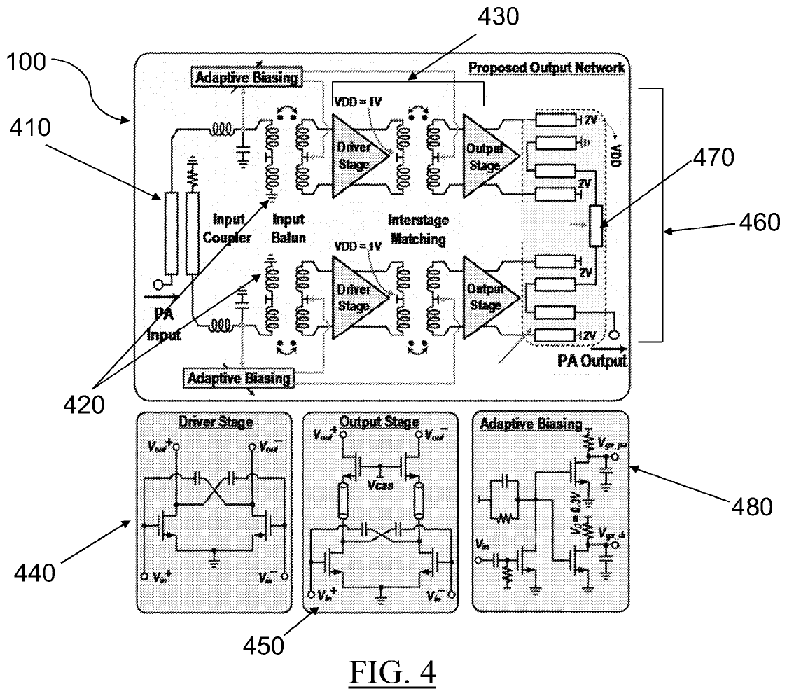

FIG. 4 is an exemplary system schematic of a wideband coupler balun 100 with load modulated power amplifiers, in accordance with an exemplary embodiment of the present disclosure. A single ended input signal received by a quadrature coupled line coupler 410, as shown in FIG. 4 near the PA Input portion of the schematic, which may split the input signal into differential signals that can therein be fed into one or more transformer baluns 420 along each electrical path. Each path may also include one or more two-stage transformer coupled PA 430, which may include a common source driver 440 and a cascode power amplifier 450. The output network 460 of the wideband coupler balun 100 with load modulated power amplifiers may include a single ended load 470 that may receive the combined power from both of the differential signal paths.

The two-stage transformer coupled power amplifier 430 can include a differential power amplifier 150 and auxiliary power amplifiers can include a common source driver stage 440 and output stage 450 having a cascode topology, as shown in FIG. 4. As one skilled in the art will appreciate, cascode topologies refer to cascode amplifiers which can typically be constructed from two transistors, such as bipolar junction transistors (BJT), field effect transistors (FET), and the like, electrically connected in series, wherein one transistor operates as a common source or common emitter and the other transistor operates as a common base or common gate. With respect to the present disclosure, the cascode topology may comprise a FET and a BJT for the driver stage 440 and output stage 450 as shown in FIG. 4. In some embodiments, one or more transmission lines can be inserted between the common source and common gate of the cascode topology, which can be advantageous for improving overall gain and stability of the amplifier.

As will be appreciated, the electrical lengths of the quadrature coupled-line coupler 410 can be configured to be the same electrical length in order to ensure maintenance of the desired phase difference between the differential power amplifier 150 and the auxiliary power amplifier 140. In some embodiments, there may also be adaptive biasing circuitry 480 within the wideband coupler balun 100 that can be disposed after the quadrature coupled line coupler 410 and before the two-stage transformer coupled power amplifier 430. The adaptive biasing circuitry 480 can be advantageous for improving the biasing properties of the auxiliary power amplifier 140 path and supporting functional cooperation with the differential power amplifier 150. The adaptive biasing circuitry 480 may include an envelope detection circuit, which can be used for sensing input signals, enveloping said input signals and converting them to a certain DC voltage, and an adaptive DC controlling circuit, which can receive the converted DC signal and generate effective gate biasing for both the driver stage 440 and the output stage 450 of the two-stage transformer coupled power amplifier 430.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and conducted in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

1. A wideband coupler balun comprising:
a differential main power amplifier configured to drive one or more balanced ports;
an auxiliary power amplifier configured to drive a driven port; and
an unbalanced port electrically terminated by a load;
wherein the wideband coupler balun is configured to:
serve as an active load modulation network for self-contained Doherty operation;
achieve differential-to-single-ended conversion; and
achieve impedance inversion,
wherein the wideband coupler balun achieves both differential-to-single-ended conversion and impedance inversion with a 90° balanced-to-unbalanced phase shift.

2. The balun of claim 1, wherein the balun has a 90° balanced-to-unbalanced phase shift.

3. The balun of claim 1 further comprising:
a first set of coupled line couplers; and
a second set of coupled line couplers;
wherein:
the driving port is electrically connected to a first end of the first set of coupled line couplers;
the unbalanced port is electrically connected to a second end of the first set of coupled line couplers; and
the one or more balanced ports are electrically connected to the second set of coupled line couplers.

4. The balun of claim 3, wherein the balun is further configured to operate at a center frequency; and
wherein the first and second coupled line couplers are configured to have a quarter wave electrical length of the center frequency.

5. The balun of claim 4, wherein the first set of coupled line couplers and the second set of coupled line couplers are configured to have a coupling factor of 1/√2.

6. The balun of claim 1, wherein the auxiliary power amplifier, when powered on, is configured to inject a signal on the driven port.

7. The balun of claim 6, wherein the auxiliary power amplifier, when powered off, causes the differential main power amplifier to drive the coupler balun one or more balanced ports.

8. The balun of claim 7, wherein the auxiliary power amplifier, when powered on, is further configured to modulate a load impedance for the differential main power amplifier.

9. The balun of claim 8, wherein the balun is further configured such that a load impedance for the differential main power amplifier is modulated based on a current ratio between the differential main power amplifier and the auxiliary power amplifier.

10. The balun of claim 1, wherein the differential main power amplifier, when powered on, is configured to inject a signal on the one or more balanced ports.

11. A a continuous coupler-Doherty-power-amplifier comprising:
one or more coupled-line couplers configured to operate at a center frequency;
a first port, a second port, and a differential port;
a differential main power amplifier electrically connected to the differential port; and
an auxiliary power amplifier electrically connected to the first port;
wherein the amplifier is configured to receive an unbalanced signal at the first port and return a balanced signal at the second port; and
wherein from 26 to 60 GHz, the amplifier achieves >19.9 dBm saturated output power (Pₛₐₜ) with >23.3% peak power-added efficiency (PAE).

12. The amplifier of claim 11, wherein:
the second port is electrically terminated with a single ended output load;
the one or more coupled line couplers are electrically connected in series; and
the one or more coupled line couplers, when operating at the center frequency, are configured to have a quarter wave electrical length of the center frequency.

13.-14. (canceled)

15. The amplifier of claim 12, wherein the one or more coupled line couplers are further configured to have a coupling factor of 1/√2 between the one or more coupled line couplers.

16. The amplifier of claim 11, wherein:
the auxiliary power amplifier, when powered on, is configured to:
inject a signal on the first port; and
modulate a load impedance for the differential main power amplifier;
the auxiliary power amplifier, when powered off, causes the differential main power amplifier to drive the amplifier; and
the differential main power amplifier, when powered on, is configured to inject a signal on the differential port.

17.-18. (canceled)

19. The amplifier of claim 16, wherein the load impedance for the differential main power amplifier is modulated based on a current ratio between the differential main power amplifier and the auxiliary power amplifier.

20. (canceled)

21. A system comprising:
a first wideband coupler balun according to claim 1; and
a second wideband coupler balun according to claim 1;
wherein the first and second coupler baluns in cascade form a series Doherty combiner network.

22. The system of claim 21, wherein the system is configured to be driven directly by linear mm-wave power amplifiers.
